(19) United States
(12) Patent Application Publication
(10) Pub. No.: US 2016/0369031 A1
(43) Pub. Date: Dec. 22, 2016

(54) PROCESS FOR THE CONTROL OF THE SURFACE ENERGY OF A SUBSTRATE

(71) Applicant: ARKEMA FRANCE, Colombes (FR)

(72) Inventors: Christophe NAVARRO, Bayonne (FR); Celia NICOLET, Talence (FR); Xavier CHEVALIER, Grenobel (FR)

(73) Assignee: Arkema France, Colombes (FR)

(21) Appl. No.: 15/117,972

(22) PCT Filed: Feb. 6, 2015
(86) PCT No.: PCT/FR2015/050285

§ 371 Date: Aug. 10, 2016

(30) Foreign Application Priority Data
Feb. 11, 2014 (FR) 1451062

(51) Int. Cl. C08F 297/02; G03F 7/00; C09D 153/00

(52) U.S. Cl. CPC C08F 297/026; C09D 153/00; G03F 7/0002

(57) ABSTRACT

The invention relates to a process for controlling the surface energy of a substrate in order to make it possible to obtain a specific orientation of the nanodomains of a film of block copolymer subsequently deposited on the said surface, the said process being characterized in that it comprises the following stages:
preparing a blend of copolymers, each copolymer comprising at least one functional group which allows it to be grafted to or crosslinked on the surface of the said substrate,
depositing the said blend thus prepared on the surface of the said substrate,
carrying out a treatment which results in the grafting to the surface of the substrate or the crosslinking on the surface of the substrate of each of the copolymers of the blend.

### FIELD OF THE INVENTION

The present invention relates to the field for the preparation of the surface of a substrate, in order to make possible the nanostructuring of a block copolymer film subsequently deposited on the surface and to control the generation of patterns and their orientation in the block copolymer film.

More particularly, the invention relates to a process for the control of the surface energy of a substrate. In addition, the invention relates to a composition used for the implementation of this process and to a process for the nanostructuring of a block copolymer.

### PRIOR ART

The development of nanotechnologies has made it possible to continually miniaturize the products of the microelectronics field and microelectromechanical systems (MEMs) in particular. Today, conventional lithography techniques no longer make it possible to meet these continuing needs for miniaturization as they do not make it possible to produce structures with dimensions of less than 60 nm.

It is therefore necessary to adapt the lithography techniques and to create etching resists which make it possible to create increasingly small patterns with high resolution. With block copolymers, it is possible to structure the arrangement of the constituent blocks of the copolymers by phase segregation between the blocks, thus forming nanodomains, at scales of less than 50 nm. As a result of this ability to self-nanostructure, the use of block copolymers in the electronics or optoelectronics field is now well known.

However, the block copolymers intended to form nanolithography resists must exhibit nanodomains which are oriented perpendicularly to the surface of the substrate, in order to be able subsequently to selectively remove one of the blocks of the block copolymer and to create a porous film with the residual block(s). The patterns thus created in the porous film can subsequently be transferred, by etching, to the underlying substrate. However, without controlling the orientation, the nanodomains tend to arrange themselves randomly. In particular, when one of the blocks of the block copolymer exhibits a preferential affinity for the surface on which it is deposited, the nanodomains then have a tendency to orient themselves parallel to the surface. This is why the desired structuring, that is to say the generation of domains perpendicular to the surface of the substrate, the patterns of which can be cylindrical, lamellar, helical or spherical, for example, require the preparation of the substrate for the purpose of controlling it surface energy.

Among the possibilities known, a statistical copolymer, the monomers of which can be identical in all or part to those used in the block copolymer which it is desired to deposit, is deposited on the substrate. In addition, if it is desired to prevent, for example, the diffusion of the statistical copolymer, it is preferable to graft and/or crosslink the copolymer to the surface by the use of appropriate functionalities. The term “grafting” is understood to mean the formation of a bond, for example a covalent bond, between the substrate and the copolymer. The term “crosslinking” is understood to mean the presence of several bonds between the copolymer chains.

Mansky et al. in Science, vol. 275, pages 1458-1460 (7 Mar. 1997), have shown that a poly(methylmethacrylate-co-styrene) (PMMA-r-PS) statistical copolymer, functionalized by a hydroxyl group at the chain end, makes possible good grafting of the copolymer at the surface of a silicon substrate exhibiting a native oxide layer (Si/native SiO₂). In et al., Langmuir 2006, Vol. 22, 7855-7860, have furthermore shown that it is advantageously possible to improve the grafting of the statistical copolymer to the surface of the substrate and in particular the rate of grafting by introducing several hydroxyl functional groups, no longer at the chain end but distributed randomly actually within the statistical copolymer. In this case, the covalent bond between the copolymer and the surface of the substrate is created by virtue of the grafting of the hydroxyl functional groups distributed within the polymer chain. The grafting of a statistical copolymer thus makes it possible to suppress the preferred affinity of one of the blocks of the block copolymer for the surface and to prevent a preferred orientation of the nanodomains parallel to the surface of the substrate from being obtained. These documents also describe that, in order to be able to obtain a surface said to be “neutral” with respect to the block copolymer when it is deposited on this surface, in order to promote an orientation of the nanodomains perpendicularly to the surface of a substrate, it is necessary to control the composition of the statistical copolymer and in particular the ratios of comonomers. This is because the surface energy, which makes it possible to obtain an orientation of the nanodomains perpendicularly to the surface and without defect, corresponds to a composition of the grafted statistical copolymer which is restricted in terms of ratios of comonomers. In point of fact, while it is possible to vary the composition of a statistical copolymer across its synthesis, it turns out on the other hand to be very difficult to reencounter, in the copolymer synthesized at the end, strictly the same ratios by weight incorporated of each comonomer, rigorously controlled before the beginning of the polymerization reaction, and also the weight initially targeted. Furthermore, the synthesis of copolymers, which can be statistical or gradient copolymers, is dependent on the chemical nature of the comonomers, with the result that it is sometimes impossible to synthesize a copolymer with a given system of comonomers.

Another approach used to orientate the nanodomains of a block copolymer on a surface consists in depositing, on the surface of the substrate, a crosslinkable statistical copolymer. D. Y. Ryu et al., Science, vol. 308, pages 236-239 (8 Apr. 2005), have demonstrated that the use of a crosslinkable statistical copolymer on the surface of the substrate makes it possible to obtain relatively thick films (from a few nm to several tens, indeed even hundreds, of nm) and on substrates where statistical copolymers graft themselves with difficulty, such as organic substrates, for example. However, with the use of crosslinkable copolymers, a limitation appears when it is desired to neutralize a surface of given topography. The deposition of the statistical copolymer, followed by its crosslinking, will completely cover the surface of a given topography, which can no longer be made use of as is, the crosslinking preventing any removal of a portion of the covered undesired surface, rendering this surface “not in accordance”. When noncrosslinked copolymers are used, it is possible to remove the statistical copolymer far off from the surface as it is nongrafted, for example by washing the surface with an appropriate solvent. Thus, after removing the excess copolymer, the topography of the initial surface is reencountered, which surface in this case is “in accordance”.

S. Ji et al., Adv. Mater., 2008, Vol. 20, 3054-3060 have furthermore described another approach for neutralising the surface of a substrate which consists in depositing, on the surface of the substrate, a ternary blend of a diblock copolymer, of low molecular weight, with its two corresponding homopolymers, of low molecular weight, each homopolymer comprising chemical functional groups which make possible grafting to the surface of the substrate. The presence of the block copolymer in the ternary blend makes it possible to homogenize the blend of the two homopolymers before they are grafted to the surface of the substrate and to thus prevent macroscopic phase separation of the homopolymers in the blend, then resulting in a nonhomogeneous functionalization of the surface. The blend, exhibiting appropriate proportions in each of the constituents, makes it possible to neutralize the surface with respect to the block copolymer deposited subsequently on this surface.

However, it is not always easy to directly find the correct proportions of homopolymers in order to obtain a neutral surface. Furthermore, if there is not sufficient block copolymer in the blend or if the copolymer does not have the correct molecular weight, a macroscopic phase segregation occurs. Consequently, it can be tedious to find the correct proportions of each of the constituents of the ternary blend.

Another technique for controlling the surface energy of a substrate in the context of the structuring of block copolymers consists in successively grafting homopolymers. This method, described by G. Liu et al., J. Vac. Sci. Technol., B27, pages 3038-3042 (2009) and by M.-S. She et al., ACS Nano, Vol. 7, No. 3, pages 2000-2011 (2013), consists in grafting, to the substrate, a first homopolymer having hydroxyl functional groups and then in grafting, to this first grafted layer, a second homopolymer having hydroxyl functional groups, each homopolymer being based on one of the constituent monomers of the self-assembled block copolymer deposited on the second grafted layer. The surface energy of the substrate is controlled by adjusting the ratios of grafted homopolymers. This control of the ratios of grafted homopolymers is carried out in particular by varying the durations and temperatures of the heat treatments necessary for the graftings, and also the molecular weights of the homopolymers.

However, it turns out that this process is tedious to carry out as a result of the large number of stages to carry out and the numerous experimental parameters to control.

S. Ji et al., Macromolecules, Vol. 43, pages 6919-6922 (2010); E. Han et al., ACS Nano, Vol. 6, No. 2, pages 1823-1829 (2012), and W. Gu et al., ACS Nano, Vol. 6, No. 11, pages 10250-10257 (2012), also describe another technique which consists in grafting, to the substrate, a block copolymer of low molar mass comprising, at one or other of its ends, a chemical functional group which makes possible the grafting, the blocks of which are identical in chemical nature to the blocks of the block copolymer intended to be deposited and self-assembled on this grafted layer. The block copolymer grafted to the surface does not exhibit phase separation as its molar mass is too small, with the result that it makes it possible to obtain a chemically homogeneous layer at the surface of the substrate.

However, if the degree of polymerization and/or the phase segregation parameter of the grafted block copolymer are poorly controlled and become too high, the surface neutralization is less effective as there is phase separation between the blocks. Furthermore, in order to make possible good grafting of the layer of block copolymer, it is necessary for the chemical functional group which makes possible the grafting of the block copolymer to be located in the block exhibiting the greater affinity for the surface.

H. S. Suh et al., Macromolecules, Vol. 43, pages 461-466 (2010), have reported the use of organosilicates for neutralising the surface of the substrate. For this, a sol-gel of silicates functionalized by organic compounds is deposited on the substrate and then crosslinked until a deposited layer which is neutral with respect to the block copolymer subsequently assembled on this deposited layer is obtained. The conditions for obtaining a neutral surface with the crosslinked sol-gel depend on the crosslinking time and on the crosslinking temperature, as well as on the type of organic compound used to functionalize the silicate.

However, it turns out that this process is limited to the production of a surface “not in accordance” and is tedious to carry out as a result of the numerous experimental parameters to be controlled.

Finally, another technique, described by J. N. L. Albert et al., ACS Nano, Vol. 3, No. 12, pages 3977-3986 (2009) and J. Xu et al., Adv. Mater., 22, pages 2268-2272 (2010), is based on the formation of self-assembled monolayers, also denoted SAMs, which are obtained with small organic molecules. A self-assembled monolayer SAM is generally obtained by vapour deposition, such as, for example, a layer of functionalized chlorosilane on a silicon substrate which has been subjected to an ultraviolet/ozone (UVO) treatment, or also by dipping the substrate in a solution containing the molecule, such as a solution based on thiols, in order to neutralize a gold surface, or based on phosphonates, in order to neutralize an oxide layer, for example. Generally, the molecule at the basis of the self-assembled monolayer SAM exhibits chemical groups, the nature of which is close to the chemical nature of the blocks of the block copolymer subsequently deposited on the monolayer, in order to prevent a preferred affinity of one of the blocks of the block copolymer for the surface. An alternative form of this method consists in depositing a self-assembled monolayer SAM on the substrate, the monolayer exhibiting an affinity for one of the blocks of a given block copolymer, then in directly modifying the SAM monolayer by UV treatment or a local oxidation, for example, in order to render it neutral with regard to the block copolymer, or in creating a chemical contrast between the unmodified region and the modified region which will make it possible to subsequently direct the orientation of the block copolymer.

However, this process is complex to carry out and exhibits several disadvantages. It necessitates finding a chemical functional group/nature of the surface pair which is appropriate. Consequently, this process can only work for a restricted set of natures of surfaces. The quality of SAM monolayers is furthermore difficult to control as multilayers may also be formed. The process requires times which are generally too long on the industrial scale, typically a few hours. Finally, there do not exist rules for finding the chemical nature of the small molecules which make possible neutralization of the substrate and the composition of the SAM does not necessarily follow the composition of the solution in the case of a mixture of small molecules.

The various approaches described above make it possible to control the orientation of a block copolymer on a pretreated surface. On the other hand, these solutions generally remain too tedious and complex to carry out, expensive and/or require treatment times which are too long to be compatible with industrial applications.

The document US2003/05947 relates to a finishing varnish composition comprising an acrylic polymer with a hydroxyl functional group. Such a composition is not intended to be used for the implementation of a process for controlling the surface energy of a substrate and it does not comprise a blend of copolymers each comprising at least one grafting or crosslinking functional group. The composition described in this document does not make it possible to neutralize the surface energy of the substrate or to orient, along a particular direction, the nanodomains of a block copolymer subsequently deposited on the surface.

The most widespread and what appears to be the least complex solution, which consists in grafting a statistical copolymer of specific composition to the surface of the substrate, makes it possible to effectively control the surface energy of the substrate. However, the difficulties of reproducibility of synthesis of a statistical or gradient copolymer with a restrictive composition in terms of ratios of comonomers and a well defined weight limit the advantage of the use of such a copolymer to easily and rapidly neutralize the surface of a substrate.

The Applicant Company has thus taken an interest in this problem and has looked for a solution in order to overcome the experimental error and the deviations with regard to the composition and the weight of the statistical copolymer, while limiting the number of syntheses necessary which increase the cost, in order to produce a specific composition which makes it possible to effectively control the surface energy of the substrate on which the composition is deposited.

### Technical Problem

The aim of the invention is thus to overcome at least one of the disadvantages of the prior art. The invention is targeted in particular at providing a simple, inexpensive and industrially realisable alternative solution in order to be able to exert fine control over the surface energy of a given substrate by the grafting and/or the crosslinking of a composition, while minimising as much as possible the number of syntheses of this composition.

### BRIEF DESCRIPTION OF THE INVENTION

To this end, a subject-matter of the invention is a process for controlling the surface energy of a substrate in order to make it possible to obtain a specific orientation of the nanodomains of a film of block copolymer subsequently deposited on the said surface, the said process being characterized in that it comprises the following stages:
preparing a blend of copolymers, each copolymer comprising at least one functional group which allows it to be grafted to or crosslinked on the surface of the substrate,
depositing the said blend thus prepared on the surface of the said substrate,
carrying out a treatment which results in the grafting to the said surface or the crosslinking on the said surface of each of the copolymers of the blend.

Thus, the process according to the invention makes it possible to precisely and easily control the ratios of comonomers of the blend by blending, in chosen proportions, polymers of known compositions. The contents of comonomers are thus simply controlled and any experimental error is avoided. Furthermore, this process also makes it possible to blend polymers each comprising comonomers which are not directly polymerizable with one another and thus to be freed from the chemical nature of the comonomers.

The constituent comonomers of each of the polymers of the blend can be at least in part different from those respectively present in each of the blocks of the block copolymer subsequently deposited on the surface in order to be nanostructured.

The invention relates in addition to a composition intended to be used for the implementation of the process for controlling the surface energy described above, characterized in that it comprises a blend of copolymers, each copolymer comprising at least one functional group which allows it to be grafted to or crosslinked on the surface of a substrate, so that, once grafted to or crosslinked on the surface of the said substrate, the said composition neutralizes the surface energy of the said substrate and makes possible a specific orientation of the nanodomains of a block copolymer subsequently deposited on the said surface.

Another subject-matter of the invention is a process for nanostructuring a block copolymer, characterized in that it comprises the stages of the process for controlling the surface energy of a substrate described above, then a stage of depositing a solution of the block copolymer on the surface of the said pretreated substrate and an annealing stage which makes possible nanostructuring of the said block copolymer by generation of nanostructured patterns oriented along a specific direction.

Finally, the invention relates to the use of the process for controlling the surface energy of a substrate described above in lithography applications.

Other distinctive features and advantages of the invention will become apparent on reading the description, made as illustrative and nonlimiting example, with reference to the appended figures, which represent:

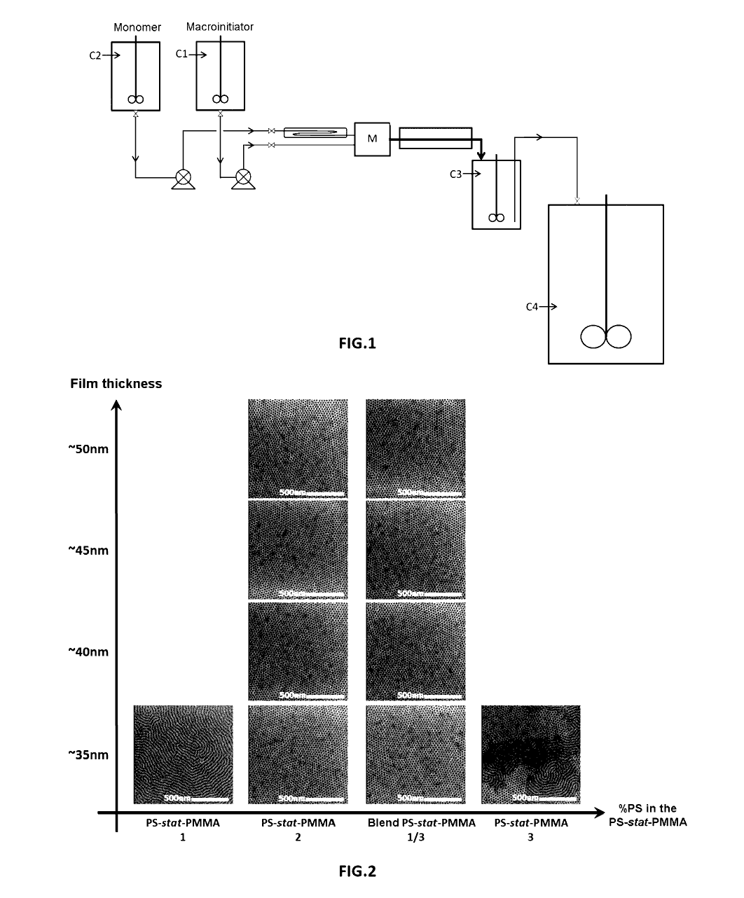

FIG. 1, a diagram of an example of a polymerization installation which can be used,

FIG. 2, photographs taken with a scanning electron microscope of samples of block copolymers self-assembled on surfaces functionalized with different compositions of copolymers.

### DETAILED DESCRIPTION OF THE INVENTION

The term “polymers” is understood to mean either a copolymer (of statistical, gradient, block or alternating type) or a homopolymer.

The term “monomer” as used relates to a molecule which can undergo a polymerization.

The term “polymerization” as used relates to the process for conversion of a monomer or of a mixture of monomers into a polymer.

The term “copolymer” is understood to mean a polymer bringing together several different monomer units.

The term “statistical copolymer” is understood to mean a copolymer in which the distribution of the monomer units along the chain follows a statistical law, for example of Bernoulli (zero-order Markov) or first-order or second-order Markov type. When the repeat units are distributed at random along the chain, the polymers have been formed by a Bernoulli process and are referred to as random copolymers. The term “random copolymer” is often used even when the statistical process which has prevailed during the synthesis of the copolymer is not known.

The term “gradient copolymer” is understood to mean a copolymer in which the distribution of the monomer units varies progressively along the chains.

The term “alternating copolymer” is understood to mean a copolymer comprising at least two monomer entities which are distributed alternately along the chains.

The term “block copolymer” is understood to mean a polymer comprising one or more uninterrupted sequences of each of the separate polymer entities, the polymer sequences being chemically different from one another and being bonded to one another via a chemical bond (covalent, ionic, hydrogen or coordination). These polymer sequences are also known as polymer blocks. These blocks exhibit a phase segregation parameter such that, if the degree of polymerization of each block is greater than a critical value, they are not miscible with one another and separate into nanodomains. It should be noted that, when such a block copolymer is used as constituent in any blend produced in the context of the present invention for functionalizing a given substrate, it will comprise, either directly inserted into the segment of one or more blocks or alternatively at one or more ends, one or more chemical functional groups which make possible the grafting of the copolymer to the substrate.

The term “homopolymer” is understood to mean a polymer consisting of just one given monomeric entity. It should be noted that, when such a homopolymer is used as constituent in any blend produced in the context of the present invention to functionalize a given substrate, it will comprise, either in the chain of monomers or at one of its ends, one or more chemical functional groups which make possible the grafting to a given substrate.

The term “miscibility” is understood to mean the ability of two or more compounds to blend together completely to form a homogeneous phase. The miscible nature of a blend can be determined when the sum of the glass transition temperatures (Tg) of the blend is strictly less than the sum of the Tg values of the compounds taken in isolation.

The principle of the invention consists in producing a composition capable of making possible control of the surface energy of a substrate in order to be able to nanostructure a block copolymer and more particularly to generate patterns (cylinders, lamellae, and the like) oriented perpendicularly to the surface of the substrate.

For this, the composition comprises a blend of polymers in which each polymer comprises at least one functional group which makes it possible to graft it to or to crosslink it on the surface of the substrate. The grafting functional groups, such as hydroxyl functional groups, for example, or the crosslinking functional groups, such as epoxy functional groups, for example, are present at the chain end or in the chains of each of the constituent polymers of the blend.

The constituent polymers in the blend can be identical or different in nature. A blend can thus comprise statistical and/or gradient and/or block and/or alternating copolymers and/or homopolymers. An essential condition is that each copolymer and/or homopolymer of the blend, whatever its nature, comprises at least one functional group which makes it possible to graft it to or to crosslinking it on the surface of the substrate.

Each constituent polymer of the blend has a known composition and is based on one or more comonomers which can be in all or part different from the comonomers at the basis of the block copolymer intended to be deposited and self-assembled on the surface. More particularly, when the blend comprises a homopolymer, the monomer at the basis of the homopolymer will be identical to one of the constituent comonomers of the other copolymers of the blend and of the constituent comonomers of the block copolymer to be nanostructured. Thus, each copolymer used in the blend can exhibit a variable number “x” of comonomers, with x taking whole values, preferably x≦7 and more preferably 2≦x≦5. The relative proportions, in monomer units, of each constituent comonomer of each copolymer of the blend are advantageously between 1% and 99%, with respect to the comonomer(s) with which it copolymerizes.

The number-average molecular weight of each polymer of the blend, measured by size exclusion chromatography (SEC) or gel permeation chromatography (GPC), is preferably between 500 and 250 000 g/mol and more preferably between 1000 and 150 000 g/mol.

The polydispersity of each polymer of the blend, which is the ratio of the weight-average molecular weights to the number-average molecular weights, for its part is preferably less than 3 and more preferably still less than 2 (limits included).

The number “n” of polymers in the blend is preferably 1<n≦5 and more preferably 2≦n≦3.

The proportion of each polymer used to produce the blend can vary from 0.5% to 99.5% by weight in the final blend.

Such a blend of polymers makes it possible to easily produce, with a minimum number of polymers, a broad range of compositions which make it possible to vary the surface energy of the substrate. In addition, this blend makes it possible to very finely and easily adjust the relative proportions of each constituent polymer of the blend. Another advantage of this blend lies in the fact that it is possible to blend polymers exhibiting all or part of their comonomers different from the comonomers at the basis of the block copolymer intended to be deposited and self-assembled on the surface, so that the surface energy is adjusted by virtue of the different comonomers present in the mixture and of their relative proportions in the different polymers. Furthermore, the chemical functional groups which make possible the grafting of the polymers to the substrate, and also their number and their position in the polymer chains, differ from one polymer to the other. The different chain ends of the polymers exposed towards the surface then make it possible, themselves also, to adjust the surface energy.

It should be noted that the possibility of blending polymers exhibiting comonomers which are in part different makes it possible to envisage surface functionalizations which it would be very difficult, indeed even impossible, to carry out without this. This is because it is well known that certain monomers, of incompatible chemical natures (for example, a comonomer A and a comonomer B), cannot be copolymerized together in the form of statistical or gradient or alternating copolymers, thus preventing the “neutralizing” of a substrate in order to orientate a block copolymer composed of the same monomers (A and B). The fact of copolymerizing these monomers separately with another, suitably chosen, comonomer (respectively C and D) in the form of statistical (A-stat-C; B-stat-D) or gradient or alternating copolymers and of then blending the copolymers thus obtained in order to modify the surface energy of a substrate will then make it possible to obtain surfaces which are “neutral” with respect to the block copolymer (A-b-B).

In this case, the other comonomers (respectively C and D), copolymerizing with each of the comonomers (respectively A and B) non-copolymerizable together, can be identical or different but will have to be miscible with one another.

This same approach can be envisaged with a blend of block copolymers (A-b-C; B-b-D) if the other comonomers (respectively C and D), copolymerizing with each of the comonomers (respectively A and B) non-copolymerizable together, carry the chemical functional groups which make it possible for each block copolymer to be grafted to or crosslinked on the surface to be neutralized.

The blend must be produced with proportions which are suitably chosen in order to obtain neutralization of the surface. For this, it is possible to make use of graphs which make it possible to know the relationship between the ratios of comonomers and the surface energy of a given substrate, in order to modify the proportions of each of the polymers, of known compositions, in the blend.

As regards the synthesis of the polymers used for the blend, they can be synthesized by any appropriate polymerization technique, such as, for example, anionic polymerization, cationic polymerization, controlled or uncontrolled radical polymerization or ring opening polymerization. In this case, the different constituent comonomer or comonomers of each polymer will be chosen from the usual list of the monomers corresponding to the polymerization technique chosen.

When the polymerization process is carried out via a controlled radical route, which is the preferred route used in the invention, any controlled radical polymerization technique can be used, whether NMP (“Nitroxide Mediated Polymerization”), RAFT (“Reversible Addition and Fragmentation Transfer”), ATRP (“Atom Transfer Radical Polymerization”), INIFERTER (“Initiator-Transfer-Termination”), RITP (“Reverse Iodine Transfer Polymerization”) or ITP (“Iodine Transfer Polymerization”). Preferably, the process for polymerization by a controlled radical route will be carried out by NMP.

More particularly, the nitroxides resulting from the alkoxyamines derived from the stable free radical (1) are preferred.

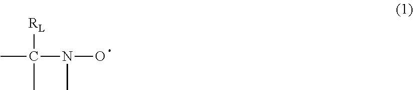

in which the radical R_{L} exhibits a molar mass of greater than 15.0342 g/mol. The radical R_{L} can be a halogen atom, such as chlorine, bromine or iodine, a saturated or unsaturated and linear, branched or cyclic hydrocarbon group, such as an alkyl or phenyl radical, or an ester —COOR group or an alkoxyl —OR group, or a phosphonate —PO(OR)₂ group, provided that it exhibits a molar mass of greater than 15.0342. The radical R_{L}, which is monovalent, is said to be in the β position with respect to the nitrogen atom of the nitroxide radical. The remaining valences of the carbon atom and of the nitrogen atom in the formula (1) can be connected to various radicals, such as a hydrogen atom or a hydrocarbon radical, such as an alkyl, aryl or arylalkyl radical, comprising from 1 to 10 carbon atoms. It is not ruled out for the carbon atom and the nitrogen atom in the formula (1) to be connected to one another via a divalent radical, so as to form a ring. However, preferably, the remaining valences of the carbon atom and of the nitrogen atom of the formula (1) are connected to monovalent radicals. Preferably, the radical R_{L} exhibits a molar mass of greater than 30 g/mol. The radical R_{L} can, for example, have a molar mass of between 40 and 450 g/mol. By way of example, the radical R_{L} can be a radical comprising a phosphoryl group, it being possible for the said radical R_{L} to be represented by the formula:

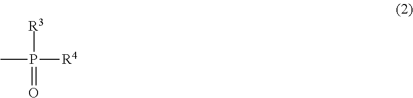

in which R³ and R⁴, which can be identical or different, can be chosen from alkyl, cycloalkyl, alkoxyl, aryloxyl, aryl, aralkyloxyl, perfluoroalkyl or aralkyl radicals and can comprise from 1 to 20 carbon atoms. R³ and/or R⁴ can also be a halogen atom, such as a chlorine or bromine or fluorine or iodine atom. The radical R_{L} can also comprise at least one aromatic ring, such as for the phenyl radical or the naphthyl radical, it being possible for the latter to be substituted, for example by an alkyl radical comprising from 1 to 4 carbon atoms.

More particularly, the alkoxyamines derived from the following stable radicals are preferred:
N-(tert-butyl)-1-phenyl-2-methylpropyl nitroxide,
N-(tert-butyl)-1-(2-naphthyl)-2-methylpropyl nitroxide,
N-(tert-butyl)-1-diethylphosphono-2,2-dimethylpropyl nitroxide,
N-(tert-butyl)-1-dibenzylphosphono-2,2-dimethylpropyl nitroxide,
N-phenyl-1-diethylphosphono-2,2-dimethylpropyl nitroxide,
N-phenyl-1-diethylphosphono-1-methylethyl nitroxide,
N-(1-phenyl-2-methylpropyl)-1-diethylphosphono-1-methylethyl nitroxide,
4-oxo-2,2,6,6-tetramethyl-1-piperidinyloxy,
2,4,6-tri(tert-butyl)phenoxy.

Preferably, the alkoxyamines derived from N-(tert-butyl)-1-diethylphosphono-2,2-dimethylpropyl nitroxide will be used.

The constituent comonomers of the polymers synthesized by the radical route will be chosen, for example, from the following monomers: vinyl, vinylidene, diene, olefinic, allyl, (meth)acrylic or cyclic monomers. These monomers are more particularly chosen from vinylaromatic monomers, such as styrene or substituted styrenes, in particular a-methylstyrene, acrylic monomers, such as acrylic acid or its salts, alkyl, cycloalkyl or aryl acrylates, such as methyl, ethyl, butyl, ethylhexyl or phenyl acrylate, hydroxyalkyl acrylates, such as 2-hydroxyethyl acrylate, ether alkyl acrylates, such as 2-methoxyethyl acrylate, alkoxy- or aryloxypolyalkylene glycol acrylates, such as methoxypolyethylene glycol acrylates, ethoxypolyethylene glycol acrylates, methoxypolypropylene glycol acrylates, methoxypolyethylene glycol-polypropylene glycol acrylates or their mixtures, aminoalkyl acrylates, such as 2-(dimethylamino)ethyl acrylate (ADAME), fluoroacrylates, silylated acrylates, phosphorus-comprising acrylates, such as alkylene glycol acrylate phosphates, glycidyl acrylate or dicyclo-pentenyloxyethyl acrylate, methacrylic monomers, such as methacrylic acid or its salts, alkyl, cycloalkyl, alkenyl or aryl methacrylates, such as methyl (MMA), lauryl, cyclohexyl, allyl, phenyl or naphthyl methacrylate, hydroxyalkyl methacrylates, such as 2-hydroxyethyl methacrylate or 2-hydroxypropyl methacrylate, ether alkyl methacrylates, such as 2-ethoxyethyl methacrylate, alkoxy- or aryloxypolyalkylene glycol methacrylates, such as methoxypolyethylene glycol methacrylates, ethoxypolyethylene glycol methacrylates, methoxypolypropylene glycol methacrylates, methoxypolyethylene glycolpolypropylene glycol methacrylates or their mixtures, aminoalkyl methacrylates, such as 2-(dimethylamino)ethyl methacrylate (MADAME), fluoromethacrylates, such as 2,2,2-trifluoroethyl methacrylate, silylated methacrylates, such as 3-methacryloyloxypropyltrimethylsilane, phosphorus-comprising methacrylates, such as alkylene glycol methacrylate phosphates, hydroxyethylimidazolidone methacrylate, hydroxyethylimidazolidinone methacrylate or 2-(2-oxo-1-imidazolidinyl)ethyl methacrylate, acrylonitrile, acrylamide or substituted acrylamides, 4-acryloylmorpholine, N-methylolacrylamide, methacrylamide or substituted methacrylamides, N-methylolmethacrylamide, methacrylamido-propyltrimethylammonium chloride (MAPTAC), glycidyl methacrylate, dicyclopentenyloxyethyl methacrylate, itaconic acid, maleic acid or its salts, maleic anhydride, alkyl or alkoxy- or aryloxypolyalkylene glycol maleates or hemimaleates, vinylpyridine, vinylpyrrolidinone, (alkoxy)poly(alkylene glycol) vinyl ethers or divinyl ethers, such as methoxypoly(ethylene glycol) vinyl ether or poly(ethylene glycol) divinyl ether, olefinic monomers, among which may be mentioned ethylene, butene, 1,1-diphenylethylene, hexene and 1-octene, diene monomers, including butadiene or isoprene, as well as fluoroolefinic monomers and vinylidene monomers, among which may be mentioned vinylidene fluoride, if appropriate protected in order to be compatible with the polymerization processes.

When the polymerization process is carried out by an anionic route, any anionic polymerization mechanism can be considered, whether ligated anionic polymerization or ring-opening anionic polymerization.

Preferably, use will be made of an anionic polymerization process in a nonpolar solvent and preferably toluene, as described in Patent EP 0 749 987, and which involves a micromixer.

When the polymers are synthesized by the cationic or anionic route or by ring opening, the constituent comonomer or comonomers of the polymers will, for example, be chosen from the following monomers: vinyl, vinylidene, diene, olefinic, allyl, (meth)acrylic or cyclic monomers. These monomers are more particularly chosen from vinylaromatic monomers, such as styrene or substituted styrenes, in particular α-methylstyrene, silylated styrenes, acrylic monomers, such as alkyl, cycloalkyl or aryl acrylates, such as methyl, ethyl, butyl, ethylhexyl or phenyl acrylate, ether alkyl acrylates, such as 2-methoxyethyl acrylate, alkoxy- or aryloxypolyalkylene glycol acrylates, such as methoxypolyethylene glycol acrylates, ethoxypolyethylene glycol acrylates, methoxypolypropylene glycol acrylates, methoxypolyethylene glycol-polypropylene glycol acrylates or their mixtures, aminoalkyl acrylates, such as 2-(dimethylamino)ethyl acrylate (ADAME), fluoroacrylates, silylated acrylates, phosphorus-comprising acrylates, such as alkylene glycol acrylate phosphates, glycidyl acrylate or dicyclo-pentenyloxyethyl acrylate, alkyl, cycloalkyl, alkenyl or aryl methacrylates, such as methyl (MMA), lauryl, cyclohexyl, allyl, phenyl or naphthyl methacrylate, ether alkyl methacrylates, such as 2-ethoxyethyl methacrylate, alkoxy- or aryloxypolyalkylene glycol methacrylates, such as methoxypolyethylene glycol methacrylates, ethoxypolyethylene glycol methacrylates, methoxypolypropylene glycol methacrylates, methoxypolyethylene glycol-polypropylene glycol methacrylates or their mixtures, aminoalkyl methacrylates, such as 2-(dimethylamino)ethyl methacrylate (MADAME), fluoromethacrylates, such as 2,2,2-trifluoroethyl methacrylate, silylated methacrylates, such as 3-methacryloyloxypropyltrimethylsilane, phosphorus-comprising methacrylates, such as alkylene glycol methacrylate phosphates, hydroxyethylimidazolidone methacrylate, hydroxyethylimidazolidinone methacrylate or 2-(2-oxo-1-imidazolidinyl)ethyl methacrylate, acrylonitrile, acrylamide or substituted acrylamides, 4-acryloylmorpholine, N-methylolacrylamide, methacrylamide or substituted methacrylamides, N-methylolmethacrylamide, methacrylamido-propyltrimethylammonium chloride (MAPTAC), glycidyl methacrylate, dicyclopentenyloxyethyl methacrylate, itaconic acid, maleic acid or its salts, maleic anhydride, alkyl or alkoxy- or aryloxypolyalkylene glycol maleates or hemimaleates, vinylpyridine, vinylpyrrolidinone, (alkoxy)poly(alkylene glycol) vinyl ethers or divinyl ethers, such as methoxypoly(ethylene glycol) vinyl ether or poly(ethylene glycol) divinyl ether, olefinic monomers, among which may be mentioned ethylene, butene, 1,1-diphenylethylene, hexene and 1-octene, diene monomers, including butadiene or isoprene, as well as fluoroolefinic monomers and vinylidene monomers, among which may be mentioned vinylidene fluoride, cyclic monomers, among each may be mentioned lactones, such as ε-caprolactone, lactides, glycolides, cyclic carbonates, such as trimethylene carbonate, siloxanes, such as octamethylcyclotetrasiloxane, cyclic ethers, such as trioxane, cyclic amides, such as ε-caprolactam, cyclic acetals, such as 1,3-dioxolane, phosphazenes, such as hexachlorocyclotriphosphazene, N-carboxyanhydrides, epoxides, cyclosiloxanes, phosphorus-comprising cyclic esters, such as cyclophosphorinanes or cyclophospholanes, oxazolines, if appropriate protected in order to be compatible with the polymerization processes, or globular methacrylates, such as isobornyl methacrylate, halogenated isobornyl methacrylate, halogenated alkyl methacrylate or naphthyl methacrylate, alone or as a mixture of at least two abovementioned monomers.

Preferably, the polymer blend will be homogeneous, that is to say that it should not exhibit macroscopic phase segregation between the copolymers of the blend. For this, the constituent polymers of the blend would have to exhibit a good miscibility.

As regards the process for controlling the surface energy of a substrate using the blend of polymers of the invention, it is applicable to any substrate, that is to say to a substrate of inorganic, metallic or organic nature.

Mention may be made, among the favoured substrates, of inorganic substrates composed of silicon or germanium exhibiting a layer of native or thermal oxide, or of aluminium, copper, nickel, iron or tungsten oxides, for example; of metallic substrates composed of gold or of metal nitrides, such as titanium nitride, for example; or of organic substrates composed of tetracene, anthracene, polythiophene, PEDOT (poly(3,4-ethylenedioxythiophene)), PSS (sodium poly(styrenesulphonate)), PEDOT:PSS, fullerene, polyfluorene, polyethylene terephthalate, polymers crosslinked in a general way (such as polyimides, for example), graphenes, BARC (Bottom Anti-reflecting Coating) anti-reflecting organic polymers or any other anti-reflecting layer used in lithography. It should be noted that the organic substrates will have to comprise chemical functional groups which make possible the anchoring of the polymers to be grafted to its surface.

The process of the invention consists more particularly of preparing the blend of polymers, of known compositions, in proportions suitably chosen in order to make possible neutralization of the surface of the substrate, and in then depositing the blend on the surface of the substrate according to techniques known to a person skilled in the art, such as, for example, the spin coating, doctor blade, knife system or slot die system technique, for example. The blend thus deposited, in a form of a film, on the surface of the substrate is subsequently subjected to a treatment for the purpose of making it possible for the polymers of the blend to be grafted to and/or crosslinked on the surface. This treatment can be carried out in different ways according to the polymers and the chemical functional groups which they include. Thus, the treatment which makes it possible for each of the polymers of the blend to be grafted to or crosslinked on the surface of the substrate can be chosen from at least one of the following treatments: a heat treatment, also known as annealing, an organic or inorganic oxidation/reduction treatment, an electrochemical treatment, a photochemical treatment, a treatment by shearing or a treatment with ionizing rays. This treatment is carried out at a temperature of less than 280° C., preferably of less than 250° C., in times of less than or equal to 10 minutes and preferably of less than or equal to 2 minutes.

A rinsing in a solvent, such as propylene glycol monomethyl ether acetate (PGMEA), for example, makes it possible subsequently to remove the excess ungrafted or noncrosslinked polymer chains. The substrate is then dried, for example under a stream of nitrogen.

The blend of polymers thus attached to the surface of the substrate makes it possible to control its surface energy with respect to a block copolymer subsequently deposited, so as to obtain a specific orientation of the nanodomains of the block copolymer with respect to the surface. According to a preferred nonlimiting form of the invention, the block copolymers deposited on the surfaces treated by the process of the invention are preferably diblock copolymers. The block copolymer is deposited by any abovementioned technique known to a person skilled in the art and is then subjected to heat treatment in order to make possible its nanostructuring to give nanodomains oriented perpendicularly to the surface.

The following example illustrates, without implied limitation, the scope of the invention.

### EXAMPLE

### Synthesis of the Statistical Copolymers

1^{st} stage: Preparation of a Hydroxy-Functionalized Alkoxyamine (Initiator) from the Commercial Alkoxyamine BlocBuilder®MA (initiator 1):

The following are introduced into a 1l round-bottom flask purged of nitrogen:
226.17 g of BlocBuilder®MA (1 equivalent)
68.9 g of 2-hydroxyethyl acrylate (1 equivalent)
548 g of isopropanol.

The reaction mixture is heated at reflux (80° C.) for 4 h and then the isopropanol is evaporated under vacuum. 297 g of hydroxy-functionalized alkoxyamine (initiator) are obtained in the form of a very viscous yellow oil.

2^{nd} stage: Preparation of Polystyrene/Polymethyl Methacrylate Copolymers

Toluene and also the styrene (S), the methyl methacrylate (MMA) and the initiator are introduced into a stainless steel reactor equipped with a mechanical stirrer and a jacket. The ratios by weight between the different monomers styrene (S) and methyl methacrylate (MMA) are described in Table 1 below. The charge by weight of toluene is set at 30% with respect to the reaction medium. The reaction mixture is stirred and degassed by bubbling with nitrogen at room temperature for 30 minutes.

The temperature of the reaction medium is then brought to 150° C.; the time t=0 is triggered at ambient temperature. The temperature is maintained at 115° C. throughout the polymerization until a conversion of the monomers of the order of 70% is reached. Samples are withdrawn at regular intervals in order to determine the kinetics of polymerization by gravimetry (measurement of solids content).

When the conversion of 70% is reached, the reaction medium is cooled to 60° C. and the solvent and residual monomers are evaporated under vacuum. After the evaporation, methyl ethyl ketone is added to the reaction medium in an amount such that a solution of copolymer of the order of 25% by weight is prepared.

This copolymer solution is then introduced dropwise into a beaker containing a nonsolvent (heptane), so as to cause the copolymer to precipitate. The ratio by weight of solvent to nonsolvent (methyl ethyl ketone/heptane) is of the order of 1/10. The precipitated copolymer is recovered in the form of a white powder after filtration and drying.

Synthesis of a PS-b-PMMA Diblock Copolymer

The installation for the polymerization used is represented diagrammatically in FIG. 1. A solution of the macroinitiator system is prepared in a vessel C1 and a solution of the monomer in a vessel C2. The stream from the vessel C2 is sent to an exchanger E in order to be brought to the initial polymerization temperature. The two streams are subsequently sent to a mixer M, which in this example is a micromixer, as described in Patent Application EP 0 749 987, and then to the polymerization reactor R, which is a normal tubular reactor. The product is received in a vessel C3 and is subsequently transferred into a vessel C4 in order to be precipitated therein.

A 21.1% by weight solution in toluene at 45° C. of the poly(styryl)CH₂C(Ph)₂Li/CH₃OCH₂CH₂OLi macroinitiator system with a molar ratio of 1/6 comprising 9.8×10⁻² mol of poly(styryl)CH₂C(Ph)₂Li as described in EP 0 749 987 and EP 0 524 054, is prepared in the vessel C1.

A 9% by weight solution of MMA, which is passed through a molecular sieve, in toluene is stored at −15° C. in the vessel C2.

The final copolymer content targeted is 16.6% by weight. The vessel C1 is cooled to −20° C. and the stream of the solution of the macroinitiator system is adjusted to 60 kg/h. The stream of the MMA solution from the vessel C2 is sent to an exchanger in order for the temperature to be lowered to −20° C. therein and the stream of the MMA solution is adjusted to 34.8 kg/h. The two streams are subsequently mixed in the static mixer and then recovered in a vessel C3, where the copolymer is deactivated by the addition of a methanol solution and then precipitated in a vessel C4 containing 7 volumes of methanol per volume of reaction mixture.

After separation and then drying, the characteristics of the block copolymer are as follows:
Mn=56.8 kg/mol
Mw/Mn=1.10
PS/PMMA ratio by weight=68.0/32.0

The measurements are carried out by SEC using polystyrene standards, with two fold detection (refractometric and UV), the UV detection making it possible to calculate the proportion of PS. If block copolymers prepared as in the present example are not used, the invention can also be carried out using other block copolymers of other provenance, provided that they exhibit identical characteristics of molecular weights, polydispersity and PS/PMMA ratio by weight.

In the example below, the statistical copolymers and the block copolymers used are based on polystyrene and polymethyl methacrylate (abbreviated to PS-stat-PMMA and PS-b-PMMA respectively).

Silicon surfaces, oriented along the crystallographic direction [1,0,0], are first of all cut up into 3×3 cm pieces. A solution of statistical copolymer or of blend of copolymers in propylene glycol monomethyl ether acetate (PGMEA) at a content of 2% by weight is deposited on the surface by any technique known to a person skilled in the art (spin coating, doctor blade, drop casting, and the like) and then evaporated, so as to leave a dry copolymer film on the substrate. The different solutions of statistical copolymer or of blend of copolymers which are compared in this example are collated in Table I below. The substrate is then annealed at 230° C. for 10 minutes, in order to graft the copolymer chains to the surface, and then the substrate is then rinsed in pure PGMEA, in order to remove the excess ungrafted polymer chains. The solution of block copolymer, dissolved at a content of 1 to 1.5% by weight in PGMEA, is subsequently deposited on the freshly functionalized surface and then evaporated, so as to obtain a dry block copolymer film having the desired thickness. The substrate is then annealed at 230° C. for 5 minutes, so as to promote the self-organization of the block copolymer over the surface. The surfaces thus organized are subsequently dipped in acetic acid for a few minutes and then rinsed with deionized water, so as to increase the contrast between the two blocks of the block copolymer, during imaging by scanning electron microscopy.

FIG. 2 represents photographs, taken with a scanning electron microscope (SEM), of several samples of a self-assembled block copolymer film, with thicknesses of between 35 and 50 nm, the block copolymer film being deposited on silicon surfaces functionalized with the different solutions of copolymers or blends of copolymers of Table I below.

TABLE I

| | Synthesis | | | |
|---|---|---|---|---|
| | % by weight of | | | |
| | initiator with | Final product characterizations | | |
| | respect to the | % | % Methyl | Mn |
| Polymer | monomers | Styrene | methacrylate | (kg/mol) |
| PS-stat-PMMA1 | 3.37 | 58 | 42 | 14.0 |
| PS-stat-PMMA2 | 3.36 | 69 | 31 | 13.7 |
| PS-stat-PMMA3 | 3.35 | 85 | 15 | 13.7 |
| Blend | / | 70 | 30 | / |
| (PS-stat-PMMA1 + | | | | |
| PS-stat-PMMA3) | | | | |

FIG. 2 shows the assembling of a PS-b-PMMA cylindrical block copolymer (PMMA cylinders in a PS matrix) for different film thicknesses, with a period of the order of 32 nm, obtained on surfaces functionalized with three pure statistical copolymers having different compositions (PS-stat-PMMA1, PS-stat-PMMA2, and PS-stat-PMMA3) and also on surfaces functionalized with a blend of PS-stat-PMMA1 and PS-stat-PMMA3 statistical copolymers, the final composition of which corresponds to that of the PS-stat-PMMA2 statistical copolymer. The SEM photographs of the films with a thickness of 35 nm show that the composition of the grafted statistical copolymer has to be finally controlled if it is desired to correctly orientate the cylinders of the block copolymer. This is because a parallel or indeed parallel/perpendicular mixed orientation of the cylinders is observed when the PS-stat-PMMA1 and PS-stat-PMMA3 statistical copolymers are respectively used, whereas a perpendicular orientation is obtained when the PS-stat-PMMA2 copolymer is grafted to the surface. It is also found that a perpendicular orientation is obtained, for the same film thickness, wherein a simple blend of PS-stat-PMMA1 and PS-stat-PMMA3 statistical copolymers having the final composition targeted is used to functionalize the surface, thus demonstrating the effectiveness of the present invention. Furthermore, it is demonstrated that the blend of PS-stat-PMMA1 and PS-stat-PMMA3 exhibits the same properties as the PS-stat-PMMA2 copolymer since a perpendicular orientation of the cylinders of the block copolymer is obtained for comparable and greater film thicknesses, both when the pure PS-stat-PMMA2 statistical copolymer and when the blend of PS-stat-PMMA1 and PS-stat-PMMA3 are employed.

1. A process for controlling the surface energy of a substrate in order to make it possible to obtain a specific orientation of the nanodomains of a film of block copolymer subsequently deposited on the said surface, wherein the process comprises the following stages:
preparing a blend of copolymers, each copolymer comprising at least one functional group which allows the copolymer to be grafted to or crosslinked on the surface of the said substrate,
depositing the said blend thus prepared on the surface of the said substrate,
carrying out a treatment which results in the grafting to the surface of the substrate or the crosslinking on the surface of the substrate of each of the copolymers of the blend.

2. The process according to claim 1, wherein the treatment resulting in the grafting or the crosslinking is carried out at a temperature of less than 280° C. in a time of less than or equal to 10 minutes.

3. The process according to claim 1, wherein the stage of grafting or crosslinking each of the copolymers of the blend is carried out by at least one of the following treatments: heat treatment, organic or inorganic oxidation/reduction treatment, electrochemical treatment, photochemical treatment, treatment by shearing or treatment with ionizing rays.

4. The process according to claim 1, wherein the number n of copolymers in the blend is such that 1<n≦5.

5. The process according to claim 1, wherein the constituent copolymers of the blend are statistical and/or gradient and/or block and/or alternating copolymers.

6. The process according to claim 1, wherein the proportions of each copolymer in the blend are between 0.5% and 99.5% by weight of the final blend.

7. The process according to claim 1, wherein each copolymer of the blend comprises a variable number x of comonomers, with x taking whole values, preferably x≦7, and more preferably still 2≦x≦5.

8. The process according to claim 1, wherein the relative proportions, in monomer units, of each constituent comonomer of each copolymer of the blend are between 1% and 99%, with respect to the comonomer(s) with which it copolymerizes.

9. The process according to claim 1, wherein the number-average molecular weight of each polymer of the blend between 500 and 250 000 g/mol.

10. The process according to claim 1, wherein the polydispersity index of each polymer of the blend is less than 3.

11. The process according to claim 1, wherein when the blend comprises block copolymers, at least one of the comonomers of each block copolymer carries the chemical functional groups which make it possible for the copolymer to be grafted to or crosslinked on the surface of the substrate.

12. The process according to claim 1, wherein the blend of copolymers additionally comprises one or more homopolymers comprising at least one functional group which makes it possible to graft it to or to crosslink it on the surface of the said substrate.

13. The process according to claim 1, wherein the substrate is selected from the group consisting of inorganic substrates, metallic substrates and organic substrates.

14. The process according to claim 13, wherein the substrate is an inorganic substrate selected from the group consisting of substrates composed of silicon or germanium exhibiting a layer of native or thermal oxide, or of aluminium, copper, nickel, iron or tungsten oxides.

15. The process according to claim 13, wherein the substrate is a metallic, substrate selected from the group consisting of substrates composed of gold or of metal nitrides.

16. The process according to claim 13, wherein the substrate is an organic substrate selected from the group consisting of substrates composed of tetracene, anthracene, polythiophene, PEDOT (poly(3,4-ethylenedioxythiophene)), PSS (sodium poly(styrene sulphonate)), PEDOT:PSS, fullerene, polyfluorene, polyethylene terephthalate, crosslinked polymers, graphenes or anti-reflecting organic polymers.

17. A composition useful for the implementation of the process for controlling the surface energy of a substrate according to claim 1, wherein the composition comprises a blend of copolymers, each copolymer comprising at least one functional group which allows it to be grafted to or crosslinked on the surface of a substrate, so that, once grafted to or crosslinked on the surface of the said substrate, the said composition neutralizes the surface energy of the said substrate and makes possible a specific orientation of the nanodomains of a block copolymer subsequently deposited on the said surface.

18. A process for nanostructuring a block copolymer, wherein the process comprises the stages of the process for controlling the surface energy of a substrate according to claim 1, then a stage of depositing a solution of the block copolymer on the surface of the said pretreated substrate and an annealing stage which makes possible nanostructuring of the said block copolymer by generation of nanostructured patterns oriented along a specific direction.

19. A lithographic method comprising using the process for controlling the surface energy of a substrate according to claim 1.

20. The process according to claim 1, wherein the number n of copolymers in the blend is such that 2≦n≦3.
